(19) United States
(12) Patent Application Publication
(10) Pub. No.: US 2004/0082141 A1
(43) Pub. Date: Apr. 29, 2004

(54) Method of fabricating a semiconductor device having trenches

(76) Inventor: Toshikazu Mizukoshi, Miyagi (JP)

Correspondence Address: RABIN & Berdo, PC, 1101 14TH STREET, NW, SUITE 500, WASHINGTON, DC, 20005, US

(21) Appl. No.: 10/635,506

(22) Filed: Aug. 7, 2003

(30) Foreign Application Priority Data
Oct. 29, 2002 (JP) 314052/2002

(51) Int. Cl. H01L 21/76

(52) U.S. Cl. 438/424; 438/435

(57) ABSTRACT

A silicon substrate at a first cornered portion 18c of each trench is subjected to a thermal oxidation after a silicon oxide film 22 is deposited in such a manner that the silicon oxide film 22 is filled inside each trench formed in a silicon substrate 10 up to the height to cover a silicon nitride film 14, thereby forming a silicon oxide film 24 at the first cornered portion and also forming a rounded fresh second cornered portion 18e.

### BACKGROUND OF THE INVENTION

1. Field of the Invention

The invention relates to a method of fabricating a semiconductor device having trenches which are used for isolating elements, particularly relates to a method of rounding a cornered portion of each trench.

2. Description of Related Art

An STI (Shallow Trench Isolation) process has recently attracted attention in place of an LOCOS (Local Oxidation Silicon) process for selectively oxidizing a semiconductor substrate as an element isolating technique for mutually isolating elements on the semiconductor substrate.

The STI method is a method of realizing isolating of elements by forming trenches on a semiconductor substrate and filling an insulating film inside trenches. According to this STI method, isolating areas are formed up to the depth of the semiconductor substrate so that each width of the isolating areas can be narrowed compared with that formed by the LOCOS method.

Accordingly, this STI method is greatly expected as an element isolating technique meeting with miniaturization of isolating areas while coming up with miniaturization of recent semiconductor integrated circuits.

The conventional STI method includes a step of forming a thermal oxide film at an inner wall of each trench with a primary purpose of rounding a surface of a semiconductor substrate at a cornered portion before filling the insulating film into each trench.

However, in the step of forming the thermal oxide film, there occurs a film stress (or stress concentration) in the cornered portion of each trench owing to a cubical expansion of a semiconductor substrate material relative to an oxide.

An oxidation speed at the cornered portion is reduced compared with an oxidation speed at areas other than the cornered portion owing to the occurrence of the film stress at the cornered portion.

As a result, the oxide film formed at the cornered portion is thinned compared with an oxide film formed at the areas other than the cornered portion and the shape of the semiconductor substrate at the cornered portion is not rounded but pointed.

Accordingly, an electric field is concentrated at the cornered portion of each trench where a parasitic transistor (or edge transistor) having a threshold voltage which is lower than a threshold voltage of a main transistor is formed.

As a result, there induces a variation of characteristics of a transistor such as the increase of leakage current (off leakage current) at a standby state of the main transistor which is caused by the formation of the parasitic transistor.

Accordingly, the invention has been developed in view of the foregoing problems, and it is an object of the invention to provide a method of fabricating a semiconductor device which realized a high reliable isolation of elements by restraining the generation of parasitic transistor having a low threshold voltage to prevent the increase of off leakage current.

### SUMMARY OF THE INVENTION

A fabrication of a semiconductor device of the invention is configured as follows. The method of fabricating the semiconductor device having trenches comprises a mask forming step comprised of sequentially forming a first insulating film and a second insulating film on a semiconductor substrate, followed by forming a mask for forming trenches on the second insulating film by patterning so as to expose a surface area of the second insulating film corresponding to each trench formed on the semiconductor substrate, a trench forming step comprised of etching a portion extending from the surface area of the exposed second insulating film to an in-depth part of the semiconductor substrate using the mask for forming trenches, thereby forming the trenches on the semiconductor substrate, a depositing step comprised of removing the mask for forming trenches, followed by depositing a third insulating film by filling a third insulating film into each trench up to the height to cover the second insulating film, a second oxide film forming step comprised of subjecting the semiconductor substrate at a cornered portion of each trench to thermal oxidation after the depositing step, thereby forming a second oxide film, a planarizing step comprises of polishing and planarizing the third insulating film so as to expose the second insulating film, and an element isolation portion forming step comprised of removing the second insulating film and the first insulating film, followed by etching the third insulating film such that a part of the third insulating film remains inside each trench, thereby forming element isolating portion;

The method comprises, according to this configuration of fabricating the semiconductor device, a silicon substrate at the cornered portion can be formed in a rounded shape by oxidizing the semiconductor substrate at the cornered portion of each trench while diffusing oxygen in the third insulating film which is filled in each trench at a high temperature.

Accordingly, concentration of electric field at the cornered portion of each trench is inhibited so that an off leakage current can be reduced compared with the prior art, thereby forming the semiconductor device in which a high reliable isolation of elements is realized.

### BRIEF DESCRIPTION OF THE DRAWINGS

FIGS. 1A to 1C are schematic sectional views for explaining a fabricating step of a semiconductor device according to a first embodiment of the invention;

FIGS. 2A to 2C are schematic sectional views for explaining the fabricating step of the semiconductor device according to the first embodiment of the invention;

FIG. 3 is a schematic sectional view for explaining the fabricating step of the semiconductor device according to the first embodiment of the invention;

FIGS. 4A and 4B are schematic sectional views for explaining a fabricating step of a semiconductor device according to a second embodiment of the invention;

FIGS. 5A to 5C are schematic sectional views for explaining a fabricating step of a semiconductor device according to a third embodiment of the invention; and

FIGS. 6A and 6B are schematic sectional view for explaining a fabricating step of a semiconductor device according to a fourth embodiment of the invention.

### DETAILED DESCRIPTION OF THE INVENTION

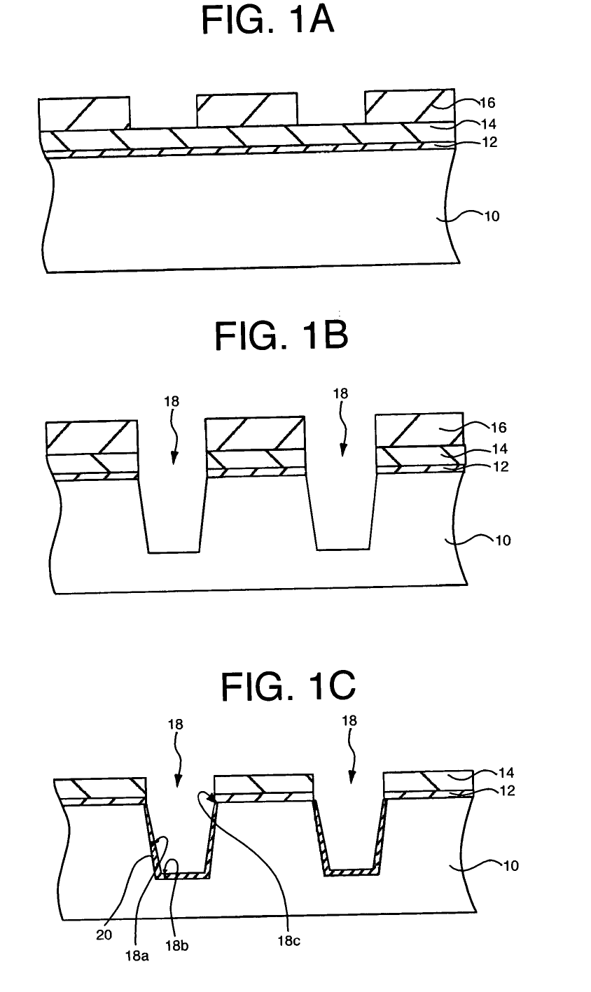

First to fourth embodiments of the invention are now described with reference to FIGS. 1 to 6. Each figure shows a step representing a method of fabricating a semiconductor device of the invention by way of section of examples of configurations thereof. Each figure merely schematically shows the shape, size, arrangement of each component to the extent that the skilled person can understand the invention, and the invention is not limited to the illustrated examples. For brevity of understanding the figures, hatching for showing the cross section is omitted except a part thereof. Although a specific material, and condition and the like are used in the following explanation but such a material and condition is one of preferred examples, and hence the invention is not limited thereto. The same components in each figure are depicted by the same reference numerals and the overlapped explanation thereof may be omitted.

A method of fabricating an element isolating portion, e.g., for isolating MOSFETs (Metal Oxide Semiconductor FETs) which are formed on a substrate is exemplified as a method of fabricating the semiconductor device of the invention in the first to fourth embodiments of the invention.

First Embodiment

A method of fabricating a semiconductor device according to a first embodiment of the invention is now described with reference to FIGS. 1 to 3.

First of all, as a mask forming step, first and second insulating films are sequentially formed on a semiconductor substrate. Thereafter, a mask for forming trenches is formed on the second insulating film by patterning so as to expose a surface area of the second insulating film corresponding to each trench which is formed on the semiconductor substrate.

As shown in FIG. 1A, a silicon oxide film (SIO₂) 12 is formed in the film thickness of 15 nm on a silicon substrate 10, e.g. at least at the temperature of 900° C. by a thermal oxidation method using dry oxygen, i.e. by a high temperature dry oxidation process.

Thereafter, a silicon nitride film (SiN) 14 is formed in the film thickness of 200 nm on the silicon oxide film 12, e.g. at a generation temperature of 700° C. by an LP-CVD (Low Pressure-Chemical Vapor Deposition) process cusing dichlorosilane (SiH₂Cl₂2) gas as main gas. The silicon oxide film 12 operates to relax a stress between the silicon substrate 10 and the silicon nitride film 14. The silicon nitride film 14 functions as a stopper film in a planarizing step as a later step.

Thereafter, a resist film is formed in the film thickness of 200 nm on the entire surface of the silicon nitride film 14 using a CVD process, then the resist film is subjected to a photolithography step to form masks 16 for forming trenches of the silicon substrate 10 by patterning.

Subsequently, an etching is performed using the masks 16 for forming trenches in the trench forming step to form trenches 18 on the silicon substrate 10. The trenches 18 are formed on a part of the silicon substrate 10 which are extended from the surface area of the exposed silicon nitride film 14 toward the in-depth of the silicon substrate 10 by way of anisotropic etching.

As shown in FIG. 1B, the silicon nitride film 14 and the silicon oxide film 12 are subjected to etching using gas mainly comprised of CF based gas. Then, the silicon substrate 10 is subjected to etching using gas comprised of mainly halogen based gas.

In such a manner, irregularities are formed on the silicon substrate 10, thereby forming trenches 18 which are recessed portions each having a depth of about 500 nm. The mask 16 for forming trenches are removed after forming the trenches 18.

Then, as a first oxide film forming step, the inner wall of each trench 18 is subjected to thermal oxidation to form a first oxide film.

As shown in FIG. 1C, a silicon oxide film 20 serving as a first oxide film is formed in film thickness of 30 nm at least at 800° C. by use of thermal oxidation process using dry oxygen.

As a result, the silicon oxide film 20 serving as the thermal oxide film is formed on the inner wall of each trench 18, i.e., a bottom portion 18a, a side wall portion 18b and a first cornered portion 18c serving as a cornered portion. It is preferable to provide the silicon oxide film 20 serving as a protection film for mainly controlling a pn junction leakage current of a main transistor.

The silicon oxide film 20 formed on the first cornered portion 18c is thinner than the bottom portion 18a and side wall portion 18b owing to a film stress caused by a cubical expansion relative to the oxide film as already explained above. The shape of the silicon substrate 10 on the first cornered portion 18c is pointed.

Then, as the depositing step, after the mask 16 for forming trenches is removed, a third insulating film 22 is deposited in such a manner that the silicon oxide film 22 is filled inside each trench 18 and has a height to cover a second insulating film 14.

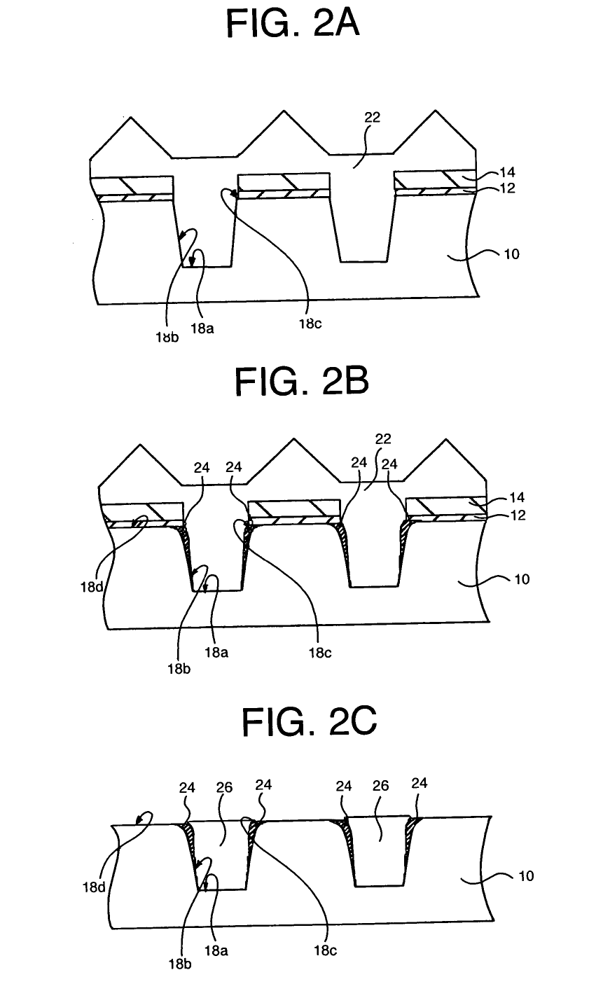

As shown in FIG. 2A, the silicon oxide film 22 serving as the third insulating film is deposited in the film thickness of 550 nm, e.g., by a HDP-CVD (High Density Plasma-CVD) process, then the silicon oxide film 22 is filled inside the trenches 18.

Then, as a second oxide film forming step, a thermal oxidation is subjected to the silicon substrate 10 at least at the first cornered portion 18c, thereby forming a second oxide film 24.

As shown in FIG. 2B, an oxicde treatment is subjected to the surface of the silicon substrate 10 for forming the trenches 18, e.g., by use of a thermal oxidation process using dry oxygen at the temperature of 1100° C., i.e., by use of a high temperature dry oxidation process.

In the oxide treatment, oxygen (O₂) is supplied to the silicon substrate 10 from the upper side of the silicon oxide film 22 and it is diffused in the silicon oxide film 22. Accordingly, oxidative reaction is started at the first cornered portion 18c which is the closest to a diffusion source, thereafter, the oxidation gradually develops from the first cornered portion 18c toward the side wall portion 18b and a convex portion 18d of the silicon substrate 10 which is covered with the silicon oxide film 12. Further, since the oxidative reaction slowly develops under a high temperature atmosphere in this configuration, viscous flow of the oxide film becomes large.

In such a manner, each silicon oxide film 24 serving as the second oxide film is locally formed at the portion mainly close to the first cornered portion 18c. Further, the film thickness of the silicon oxide film 24 serving as the thermal oxide film is gradually thinner from the cornered portion toward the side wall portion 18b and the convex portion 18d.

As a result, the concentration of a film stress toward the first cornered portion 18c is effectively inhibited, and a rounded fresh second cornered portion 18e is formed on the cornered portion of each trench 18.

Then, as a planarizing step, the silicon oxide film 22 is polished and planarized so as to expose the surface of the second insulating film 14.

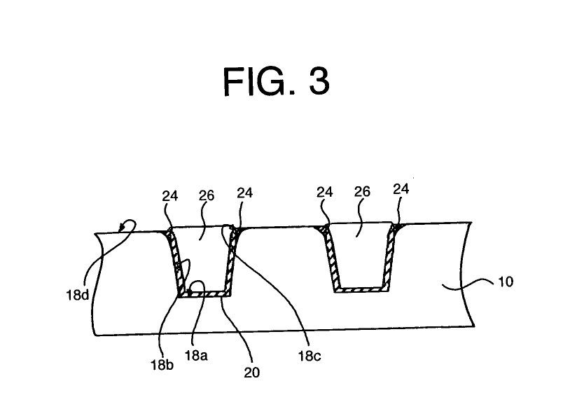

As shown in FIG. 2C, the silicon oxide film 22 which is deposited on the silicon nitride film 14 is polished using a CMP(Chemical Mechanical Polishing) process to expose the surface of the silicon nitride film 14 serving as a stopper film. Meanwhile, a remaining film thickness of the silicon oxide film 22 is set such that the height of the surface of each element isolating portion 26 and that of the silicon substrate 10 become substantially the same, namely, the difference in level (step) is not present by use of the CMP process in the later step (see FIG. 3).

Thereafter, as an element isolating portion forming step, the first insulating film 12 and the second insulating film 14 are removed and the third insulating film 22 is subjected to etching so that a part of the silicon oxide film 22 remains inside each trench 18, thereby forming each element isolating portion 26.

As shown in FIG. 3, the silicon nitride film 14 is first removed by wet etching using a thermal phosphoric acid (H₃PO₄). As an etching rate of the silicon nitride film 14 relative to the thermal phosphoric acid is remarkably greater than that of the silicon oxide film 22, the silicon nitride film 14 is selectively removed. Thereafter, the exposed silicon oxide film 12 is removed and the silicon oxide film 22 at the portion other than the interior of each trench 18 is removed by wet etching using hydrofluoric (HF) aqueous solution (hydrofluoric acid).

In such a manner, it is possible to form the element isolating portion 26, wherein the silicon oxide film 22 is filled in each trench 18.

Thereafter, ion is implanted in a transistor forming area to form a source/drain electrode, then a gate oxide film and a gate electrode are sequentially formed on the silicon substrate 10, thereby forming a MOSFET (not shown).

As described in detail above, since the second oxidizing step is performed after the depositing step according to the first embodiment of the invention, the silicon substrate is locally oxidized at least at the cornered portion of each trench at a high temperature by oxygen which diffuses in the filling material into each trench.

As a result, the film stress which is concentrated at the cornered portion of the each trench where the silicon substrate material is subjected to a cubical expansion relative to an oxide can be relaxed compared with the prior art, so that the silicon substrate at the cornered portion can be rounded.

Accordingly, the concentration of electric field at the cornered portion of each trench can be inhibited, thereby reducing an off leakage current compared with the prior art.

Therefore, a semiconductor device in which a high reliable isolation of elements is realized can be obtained.

Second Embodiment

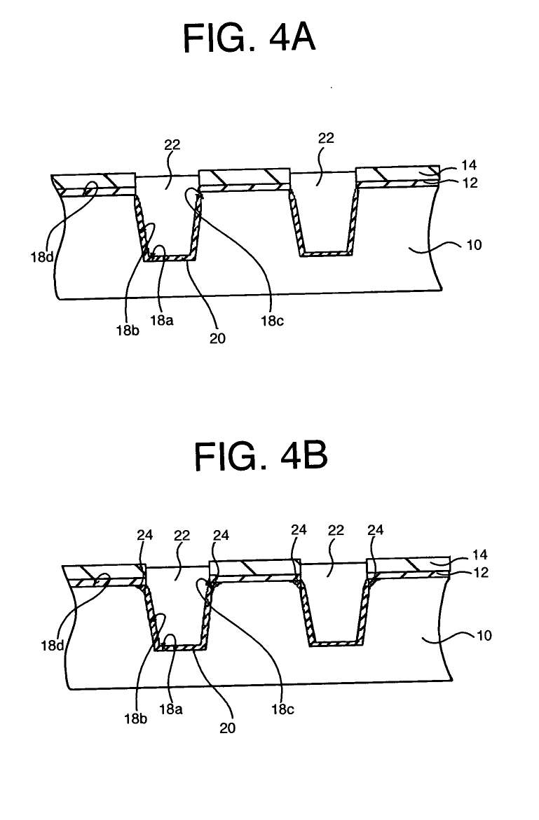

A method of fabricating a semiconductor device according to a second embodiment of the invention is now described with reference to FIGS. 4A and 4B.

The second embodiment is different from the first embodiment mainly in respect of the planarizing step which is performed before the second oxide film forming step. The constituents which are the same as those of the first embodiment are depicted by the same reference numerals and a concrete explanation thereof is omitted (this is also applied to each embodiment described later).

First of all, steps starting from a mask forming step to a depositing step are performed in the same manner as those described in the first embodiment of the invention (see FIG. 2A).

Thereafter, according to the configuration of the second embodiment, the planarizing step is performed, as shown in FIG. 4A, in the same manner as the first embodiment of the invention.

After the planarizing step is performed, a second oxide film forming step is performed, as shown in FIG. 4B, in the same manner as that of the first embodiment, so that a silicon oxide film 24 is formed in the range substantially same as that of the first embodiment.

Since the planarizing step has been already performed before the second oxide film forming step is performed in the second embodiment, a distance between the diffusion source disposed over a silicon oxide film 22 and a first cornered portion 18c is shorter than that of the first embodiment.

As a result, a thermal oxidizing time for forming the silicon oxide film 24 serving as the second oxide film can be cut down compared with the first embodiment.

Thereafter, an element isolating portion forming step is performed in the same manner as the first embodiment (see FIG. 3).

As is evident from the explanation set forth above according to the second embodiment, it is possible to obtain the same effect as the first embodiment.

Further, according to the second embodiment, since the thermal oxidizing time for forming the second oxide film can be cut down compared with the first embodiment, the semiconductor device can be fabricated at a lower cost compared with the first embodiment.

Third Embodiment

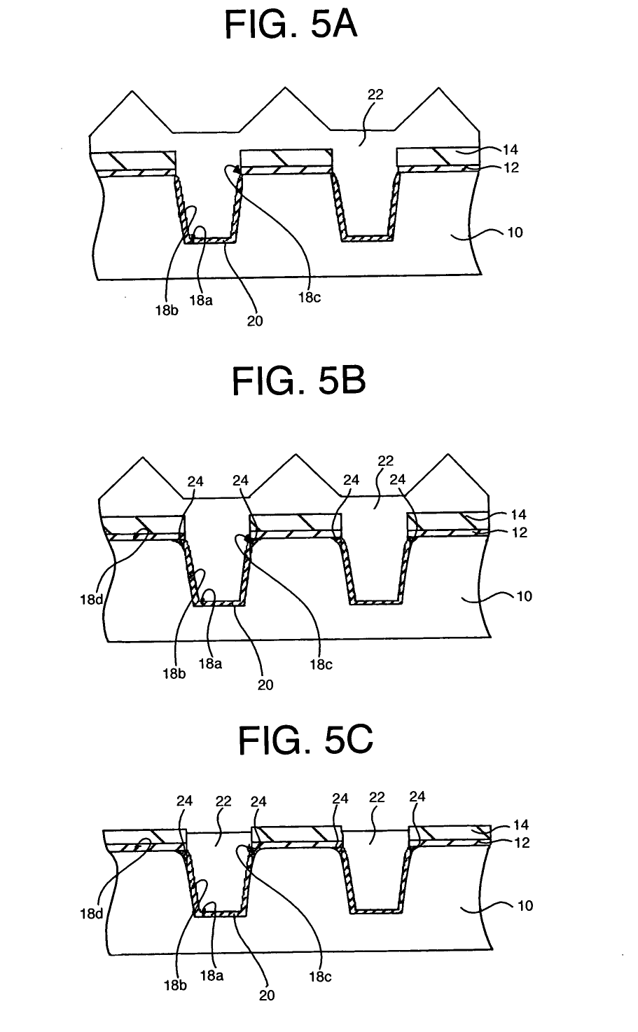

A method of fabricating a semiconductor device according to a third embodiment of the invention is now described with reference to FIGS. 5A to 5C.

The third embodiment is different from the first embodiment mainly in respect of the lack of the first oxide film forming step.

There is a product which can obtain a desired electric property and practically endure even if a thermal oxide film is not formed on all the areas of the bottom portion and the side wall portion of each trench of the semiconductor device provided with element isolating portions.

First of all, steps starting from a mask forming step to a trench forming step are performed in the same manner as those of the method described in the first embodiment (see FIG. 1B).

Thereafter, as shown in FIG. 5A, according to the third embodiment, a depositing step is performed in the same manner as that of the first embodiment without performing the first oxide film forming step.

Then, steps starting from a second oxide film forming step to an element isolating portion forming step are performed in the same manner as those of the first embodiment.

In the second oxide film forming step according to the configuration of the third embodiment, as shown in FIG. 5B, oxygen is supplied to a silicon substrate 10 from the upper side of a silicon oxide film 22 in the same manner as the first embodiment and it is diffused into the silicon oxide film 22. Accordingly, an oxidative reaction is started from a first cornered portion 18c which is the closest to a diffusion source, and then oxidation develops gradually from the first cornered portion 18c toward a side wall portion 18b and a convex portion 18d.

Since the first oxide film forming step is not performed according to the configuration of the third embodiment like the first embodiment, a first oxide film 20 is not formed on an inner wall of each trench 18.

However, according to the second oxide film forming step, a silicon oxide film 24 serving as a thermal oxide film is formed on the silicon substrate 10 at the portion extending from the cornered portion to a side wall portion 18b of each trench in the range wider than that of the first embodiment. At this time, the film thickness of the silicon oxide film 24 is gradually thinned from the cornered portion toward the side wall portion 18b and a convex portion 18d.

As set forth above, in the second oxide film forming step according to the configuration of the third embodiment, the oxidation at the side wall portion 18b of each trench 18 is also performed by setting an oxidizing time at an arbitrary and preferable value.

Thereafter, steps starting from a planarization step to an element isolating portion forming step are performed in the same manner as the first embodiment (see FIG. 5C).

As is evident from the explanation set forth above, according to the third embodiment, it is possible to obtain the same effect as the first embodiment.

Further, according to the third embodiment, the first oxide film forming step can be omitted relative to a product which can obtain a desired electric property even if the thermal oxide film is not formed on all the inner walls of the trenches 18.

Accordingly, since the number of fabricating steps can be reduced compared with those of the first embodiment, the semiconductor device can be fabricated at a low cost compared with the first embodiment.

Fourth Embodiment

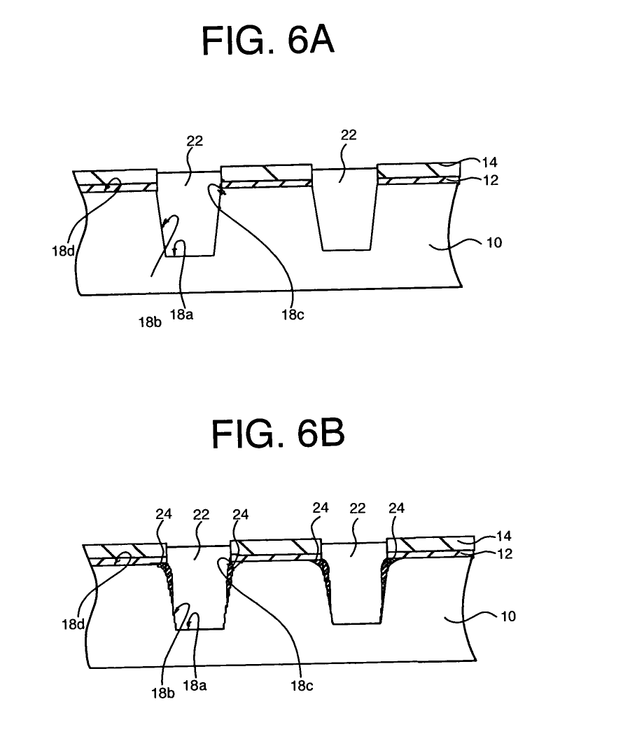

A method of fabricating a semiconductor device according to a fourth embodiment of the invention is now described with reference to FIGS. 6A and 6B.

The fourth embodiment is different from the third embodiment mainly in respect of a planarizing step which is performed before a second oxide film forming step.

Steps starting from a mask forming step to a depositing step are performed in the same manner as those of the third embodiment (see FIG. 5A).

Thereafter, according to the configuration of the fourth embodiment, the planarizing step is performed in the same manner as that of the first embodiment as shown in FIG. 6A.

Then, the second oxide film forming step is performed as shown in FIG. 6B, in the same manner as that of the first embodiment, thereby forming a silicon oxide film 24 in the range substantially the same as that of the third embodiment.

Since the planarizing step has been already performed before the second oxide film step is performed according to the configuration of the fourth embodiment, a distance between a diffusion source and a first cornered portion 18c is shortened compared with the third embodiment.

As a result, a thermal oxidizing time for forming the silicon oxide film 24 can be cut down compared with the third embodiment.

Then, an elements isolating portion forming step is performed (see FIG. 5C) in the same manner as that of the first embodiment.

As is evident from the explanation set forth above, according to the fourth embodiment, it is possible to obtain the same effect as the third embodiment.

Further, according to the fourth embodiment, since the thermal oxidizing time for forming the second oxide film can be cut down compared with the third embodiment, the semiconductor device can be fabricated at a cost which is much lower than that of the third embodiment.

As set forth above, the invention is not limited to the combination of the first to fourth embodiments of the invention. Accordingly, the invention can be applied to any preferable combination of conditions in an arbitrary preferable stage.

For example, although there are explained the method of fabricating the element isolating portion for mutually isolating the MOSFETs which are formed on the substrate in each embodiment of the invention, the invention is not limited thereto. Accordingly, the invention can be applied to an element isolating portion which can mutually isolate arbitrary preferable semiconductor devices.

As is evident from the explanation set forth above, the semiconductor substrate at the cornered portion can be rounded by subjecting the semiconductor substrates at the cornered portion of each trench to oxidation while diffusing oxygen into the third insulating film serving as a filling material into each trench at high temperature.

Accordingly, concentration of an electric field at the cornered portion of each trench can be inhibited so that an off leakage current can be reduced compared with the prior art, thereby fabricating the semiconductor device in which a high reliable isolation of elements is realized.

What is claimed is:

1. A method of fabricating a semiconductor device having trenches comprising:
a mask forming step comprised of sequentially forming a first insulating film and a second insulating film on a semiconductor substrate, followed by forming a mask for forming trenches on the second insulating film by patterning so as to expose a surface area of the second insulating film corresponding to each trench formed on the semiconductor substrate;
a trench forming step comprised of etching a portion extending from the surface area of the exposed second insulating film to an in-depth part of the semiconductor substrate using the mask for forming trenches, thereby forming the trenches on the semiconductor substrate;
a depositing step comprised of removing the mask for forming trenches, followed by depositing a third insulating film by filling a third insulating film into each trench up to the height to cover the second insulating film;
a second oxide film forming step comprised of subjecting the semiconductor substrate at a cornered portion of each trench to thermal oxidation after the depositing step, thereby forming a second oxide film;
a planarizing step comprises of polishing and planarizing the third insulating film so as to expose the second insulating film; and
an element isolation portion forming step comprised of removing the second insulating film and the first insulating film, followed by etching the third insulating film such that a part of the third insulating film remains inside each trench, thereby forming element isolating portion;

2. The method of fabricating a semiconductor device having trenches according to claim 1, further including a first oxide film forming step comprises of subjecting an inner wall of each trench to a thermal oxidation which is performed after the trench forming step is performed and before the depositing step thereby forming a first oxide film.

3. The method of fabricating a semiconductor device having trenches according to claim 1, wherein the planarizing step is performed before the second oxide film step is performed.

4. The method of fabricating a semiconductor device having trenches according to claim 1, wherein the first insulating film is a silicon oxide film and the second insulating film is a silicon nitride film.

5. The method of fabricating a semiconductor device having trenches according to claim 1, wherein the third insulating film is a silicon oxide film.

6. The method of fabricating a semiconductor device having trenches according to claim 4, wherein the third insulating film is a silicon oxide film.

7. The method of fabricating a semiconductor device having trenches according to claim 1, wherein the third insulating film is formed by an HDP-CVD method.

8. The method of fabricating a semiconductor device having trenches according to claim 5, wherein the third insulating film is formed by an HDP-CVD method.

9. The method of fabricating a semiconductor device having trenches according to claim 6, wherein the third insulating film is formed by an HDP-CVD method.
